(19) United States
(12) Patent Application Publication
(10) Pub. No.: US 2025/0192255 A1
(43) Pub. Date: Jun. 12, 2025

(54) BATTERY SYSTEM

(71) Applicant: Prime Planet Energy & Solutions, Inc., Tokyo (JP)

(72) Inventor: Junya YANO, Kato-shi (JP)

(21) Appl. No.: 18/967,657

(22) Filed: Dec. 4, 2024

(30) Foreign Application Priority Data
Dec. 8, 2023 (JP) 2023-207624

(51) Int. Cl. H01M 10/48; B60L 58/10; G01R 31/3842; H01H 85/02; H01M 10/42; H01M 50/583

(52) U.S. Cl. CPC H01M 10/48; G01R 31/3842; H01H 85/0241; H01M 10/425; H01M 50/583; B60L 58/10; H01M 2200/103

(57) ABSTRACT

A battery system includes a battery, a first main relay, and a second main relay. The battery includes a positive electrode and a negative electrode. The first main relay is connected in series to the positive electrode of the battery. The second main relay is connected in series to the negative electrode of the battery. At least one of the first main relay and the second main relay includes a relay group including a plurality of relays connected in parallel.

### CROSS REFERENCE TO RELATED APPLICATIONS

The present application claims priority from Japanese Patent Application No. 2023-207624 filed on Dec. 8, 2023, which is incorporated by reference herein in its entirety.

### BACKGROUND

The present disclosure relates to battery systems.

JP 2019-129568 A discloses a battery system including a plurality of battery modules and a plurality of switches. The plurality of battery modules are allowed to be switchable by a plurality of switches between a series state, in which the battery modules are connected in series, and a parallel state, in which the battery modules are connected in parallel. The battery system switches between the series state and the parallel state of the plurality of battery modules according to the degree of deterioration of the battery modules. It is stated that such a battery system is able to suitably avoid a situation in which the battery system becomes unusable due to a switch becoming uncontrollable to be opened/closed.

JP 2013-081316 A discloses a charging control device for a power supply device capable of switching a connection mode for a plurality of electricity storage units between series and parallel. The charging control device selects the connection mode at the start of charging based on the temperature and SOC of the power supply device. The charging control device controls the charging current in parallel connection using an upper limit value greater than the upper limit value of the charging current in series connection that is input to the power supply device. It is stated that such a charging control device is able to charge and discharge the power supply device in a short time while reducing the deterioration of battery performance.

### SUMMARY

The present inventor intends to improve user convenience of battery systems.

A battery system disclosed herein includes a battery, a first main relay, and a second main relay. The battery includes a positive electrode and a negative electrode. The first main relay is connected in series to the positive electrode of the battery. The second main relay is connected in series to the negative electrode of the battery. At least one of the first main relay and the second main relay includes a relay group including a plurality of relays connected in parallel. The plurality of relays are each individually controlled to be switched between a closed state and an open state. Such a battery system is able to improve the user convenience of the battery system.

### BRIEF DESCRIPTION OF THE DRAWINGS

FIG. 1 is a schematic view illustrating a battery system 100.

FIG. 2 is a flowchart illustrating processes executed by a controller 40.

FIG. 3 is a graph illustrating changes in current and voltage and statuses of relays 21, 22, 31, and 32 during charging.

FIG. 4 is a schematic view illustrating a battery system 100A.

### DETAILED DESCRIPTION

Hereinbelow, embodiments of the technology according to the present disclosure will be described with reference to the drawings. It should be noted, however, that the disclosed embodiments are, of course, not intended to limit the disclosure. The drawings are depicted schematically and do not necessarily accurately depict actual objects. The features and components that exhibit the same effects are designated by the same reference symbols as appropriate, and the description thereof will not be repeated as appropriate. Unless specifically stated otherwise, the recitation of numerical ranges in the present description, such as “X to Y”, is meant to include any values between the upper limits and the lower limits, inclusive, that is, “greater than or equal to X to less than or equal to Y”.

### Battery System 100

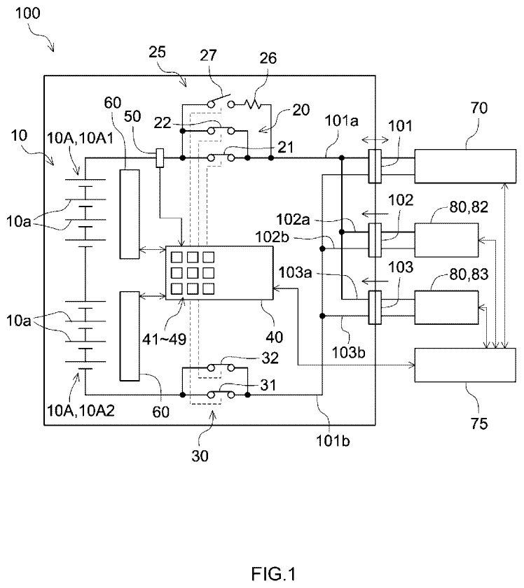

FIG. 1 is a schematic view illustrating a battery system 100. As illustrated in FIG.

1, the battery unit 100 includes a battery 10, a first main relay 20, and a second main relay 30. The battery system 100 also includes a controller 40. The controller 40 individually controls each of the relays contained in the first main relay 20 and the second main relay 30 to be opened and closed. The battery system 100 is an assembled component also referred to as a battery pack, which includes a battery and, in addition, a configuration for controlling the battery. The battery system 100 is provided with connecting portions 101 to 103. The connecting portions 101 to 103 are portions that are configured to be connectable with external chargers 80 and an external load 70.

In this embodiment, the battery system 100 is connected to the load 70 through a connecting portion 101. The load 70 is supplied with electric power from the battery 10 of the battery system 100. In this embodiment, the load 70 is a load in an electrically powered vehicle, which may include an electric motor, an inverter, or the like of the vehicle. The battery system 100 is not limited to such an embodiment but may be applicable to battery systems other than those incorporated in electrically powered vehicles.

### Battery 10

The battery 10 includes a positive electrode and a negative electrode. The battery 10 is an electricity storage device that is capable of extracting electric energy therefrom. The battery 10 stores electric power supplied from a charger 80. The battery 10 is connected to the load 70 through the connecting portion 101. The battery 10 supplies electric power to the load 70.

The battery 10 may include a secondary battery in which repeated charging and discharging are possible by means of migration of charge carriers through an electrolyte between a pair of electrodes (positive electrode and negative electrode). The battery 10 may include a lithium-ion secondary battery, a nickel-metal hydride battery, or the like, for example. The battery 10 may be a single cell battery 10a or may be a battery module 10A in which a plurality of single cell batteries 10a are electrically connected to each other via a bus bar. In this embodiment, the battery 10 includes two battery modules 10A. The two battery modules 10A are connected in series. The single cell batteries that constitute a battery module may be connected in series, connected in parallel, or connected in a combination of series and parallel connections. In this embodiment, the battery module 10A includes a plurality of single cell batteries 10a that are connected in series.

The battery 10 in the battery system 100 is charged by the charger 80. The battery 10 is connected to the charger 80 via connecting portions 102 and 103. The battery system 100 is configured to be connectable to either of a charger 82 for normal charging (hereinafter also referred to as a “normal charger 82”) and a charger 83 for rapid charging (hereinafter also referred to as a “rapid charger 83”). The battery system 100 may be connected to the normal charger 82 via the connecting portion 102. The battery system 100 may be connected to the rapid charger 83 via the connecting portion 103. The normal charger 82 and the rapid charger 83 may be connected to a common connecting portion.

For the normal charger 82 for vehicle on-board batteries, the output power of the normal charger 82 may be about 1 kW to about 6 kW. During charging with the normal charger 82, the electric current flowing through the battery 10 may be about 5 A to about 15 A. The rapid charger 83 is a charger for charging with a higher output power than the normal charger 82. For the rapid charger 83 for vehicle on-board batteries, the output power of the rapid charger 83 may be about 50 kW to about 350 KW. During charging with the rapid charger 83, the electric current flowing through the battery 10 may be about 100 A to about 400 A. The output power and the electric current during normal charging and rapid charging are not limited to the values mentioned above. The output power and the electric current during normal charging and rapid charging may vary depending on, for example, the usage of the battery system 100 or the like. For example, when the battery system 100 is used for mobile terminals or the like, such as notebook computers, smartphones, tablet terminal devices, or the like, the output power and the electric current during normal charging and during rapid charging are lower than the values mentioned above.

The battery 10 and the connecting portion 101 are connected to each other via connecting wires 101a and 101b. The connecting wire 101a is connected to the positive electrode side of the battery 10. The connecting wire 101b is connected to the negative electrode side of the battery 10. Connecting wires 102a and 102b extending from the connecting portion 102 are connected to the connecting wires 101a and 101b, respectively. Connecting wires 103a and 103b extending from the connecting portion 103 are connected to the connecting wires 101a and 101b, respectively. The first main relay 20 and the second main relay 30 are respectively provided at respective one ends of the connecting wires 101a and 101b, extending from the connecting portion 101.

The first main relay 20 and the second main relay 30 are provided between the battery 10 and the connecting portion 101. The first main relay 20 and the second main relay 30 allow switching between connection and disconnection with the load 70 and the charger 80.

### First Main Relay 20

The first main relay 20 is connected in series to the positive electrode of the battery 10. The first main relay 20 switches a connection status between the battery 10, the load 70, and the charger 80 on the positive electrode side of the battery 10. The first main relay 20 includes relay groups 21 and 22 (a plurality of relays 21 and 22). In the relay groups 21 and 22, a plurality of relays 21 and 22 are connected in parallel. The plurality of relays 21 and 22 are each configured to be individually switchable between a closed state and an open state.

### Second Main Relay 30

The second main relay 30 is connected in series to the negative electrode of the battery 10. The second main relay 30 switches a connection status between the battery 10, the load 70, and the charger 80 on the negative electrode side of the battery 10. As with the first main relay 20, the second main relay 30 includes relay groups 31 and 32 (a plurality of relays 31 and 32). In the relay groups 31 and 32, a plurality of relays 31 and 32 are connected in parallel. The plurality of relays 31 and 32 are each configured to be individually switchable between a closed state and an open state. The relays 21, 22, 31, and 32 are not particularly limited as long as they are capable of switching the connection and disconnection of the battery 10, the load 70, and the charger 80. For the relays 21, 22, 31, and 32, it is possible either to use electromechanical relays or to use semiconductor relays.

In the battery system 100, both the first main relay 20 and the second main relay 30 include a relay group in which a plurality of relays (the relays 21 and 22 in the first main relay 20 and the relays 31 and 32 in the second main relay 30) are connected in parallel.

The first main relay 20 is connected in parallel with a pre-charge circuit 25 that prevents inrush current from flowing into the load 70 and the battery 10.

### Pre-charge Circuit 25

The pre-charge circuit 25 is provided on the positive electrode side of the battery 10. The pre-charge circuit 25 is a circuit including a pre-charge resistor 26 and a pre-charge relay 27 that are connected in series. The pre-charge circuit 25 is a circuit that prevents inrush current from flowing when electric power is supplied from the charger 80 to the battery system 100, when electric power is supplied from the charger 80 to the battery system 100, and the like.

Before the load 70 is started up, the first main relay 20, the second main relay 30, and the pre-charge relay 27 are in the open state. When the load 70 is started up, the second main relay 30 and the pre-charge relay 27 are switched to the closed state. The switching of the pre-charge relay 27 may be controlled by the controller 40. The load 70 is connected to the battery system 100 via the pre-charge circuit 25. At this time, because the pre-charge circuit 25 is provided with the pre-charge resistor 26, the load 70 is supplied with electric power from the battery 10 at a low current. Thereafter, with the potential of the load 70 being high, the first main relay 20 is brought into the closed state, and subsequently the pre-charge relay 27 is brought into the open state. This prevents a high current from flowing when the load 70 is started up.

Also, prior to charging the battery 10, the first main relay 20, the second main relay 30, and the pre-charge relay 27 are in the open state. When charging the battery 10, the second main relay 30 and the pre-charge relay 27 are switched to the closed state. The load 70 is connected to the charger 80 via the pre-charge circuit 25. At this time, because the pre-charge circuit 25 is provided with the pre-charge resistor 26, the battery 10 is supplied with electric power from the battery 80 at a low current. Thereafter, with the potential of the battery 10 being high, the first main relay 20 is brought into the closed state, and subsequently the pre-charge relay 27 is brought into the open state. This prevents a high current from flowing when starting to charge the battery 10. This opening and closing of the pre-charge relay 27 described above is also referred to as a pre-charge sequence.

Meanwhile, when charging a battery, it is sometimes the case that the battery may undergo rapid charging in order to reduce the charging time. When the battery undergoes rapid charging, the battery needs to be charged with a high power. On the other hand, in order to achieve a long time operation at one time charging, it is sometimes the case that a high capacity battery may be used. In this case as well, the battery may undergo rapid charging in order to reduce the charging time. Furthermore, also when the electric energy charged in the battery is supplied (i.e., discharged) to an external load, a high current may flow into the external load depending on the usage of the battery system. Thus, a high current may flow in a charging and discharging circuit for batteries. When electric current flows, the charging and discharging circuit may generate heat due to the resistance resulting from the components that constitute the circuit. For example, a relay that switches connection between a battery and a load may generate heat in response to the contact resistance in the closed state. Such heat generation becomes greater when the electric current flowing in the circuit is higher. Also, in order to decrease the contact resistance in the relay to reduce the heat generation, a large-sized relay designed according to the charging/discharging current may be used as the main relay.

In the above-described embodiment, the battery unit 100 includes a battery 10, a first main relay 20, and a second main relay 30. The battery 10 includes a positive electrode and a negative electrode. The first main relay 20 is connected in series to the positive electrode of the battery 10. The second main relay 30 is connected in series to the negative electrode of the battery 10. The first main relay 20 includes relay groups 21 and 22 in which a plurality of relays 21 and 22 are connected in parallel. Such a configuration allows the electric current flowing in the relays 21 and 22 of the in the first main relay 20 to be divided. This reduces heat generation each of the relays 21 and 22. As a result, the relays 21 and 22 are unlikely to cause a failure resulting from the deterioration of the relays 21 and 22 due to heat (i.e., such as contact welding or the like). The battery system 100 as described above can easily adapt rapid charging or the like in which a high current flows in the battery 10, enhancing the user convenience of the battery system 100.

In addition, the battery system 100 may be able to reduce the weight of relays in comparison with the cases where large-sized relays are used for the main relays. This may reduce the energy required for driving the relays. The battery system 100 is able to use small-sized relays, which increases the number of options in selecting the components and thus reduces manufacturing costs.

In the above-described embodiment, the second main relay 30 includes relay groups 31 and 32 in which a plurality of relays 31 and 32 are connected in parallel, as with the first main relay 20. Both the first main relay 20 and the second main relay 30 include relay groups including a plurality of relays connected in parallel. Such a configuration may reduce heat generation in each of the relays 21, 22, 31, and 32 at both the positive electrode side and the negative electrode side of the battery 10. Moreover, because relay groups are provided on both the positive electrode side and the negative electrode side of the battery 10, the redundancy provides improved reliability of the battery system 100.

It should be noted that relay groups may not necessarily be provided in both of the first main relay 20 and the second main relay 30. Relay groups may be provided only in the first main relay 20, or alternatively, only in the second main relay 30. In the above-described embodiment, each of the first main relay 20 and the second main relay 30 includes two relays. However, such an embodiment is merely illustrative, and each of the first main relay 20 and the second main relay 30 may include three or more relays. The number of relays may be determined based on the current value that can flow in the charging and discharging circuit.

In the battery system 100, switching between the open state and the closed state of the plurality of relays 21, 22, 31, and 32 is controlled by the controller 40.

### Controller 40

The controller 40 individually switches each of the plurality of relays 21, 22, 31, and 32 between a closed state and an open state according to a predetermined condition. The controller 40 may be a computer, such as an ECU (electronic control unit) or a circuit board with a built-in microcomputer, for example. The computer performs required functions according to, for example, a predetermined program. Various functions of the computer may be processed by cooperation of software with an arithmetic unit [also referred to as a processor, CPU (central processing unit), or MPU (micro-processing unit)] and a memory storage device (such as a memory and a hard disk) of the computer.

The controller 40 includes a communication unit 41, a mode determining unit 42, a mode setting unit 43, a permissible current determining unit 44, an instruction unit 45, a voltage determining unit 46, a current determining unit 47, an end determining unit 48, and a memory storage unit 49. The various units 41 to 49 of the controller 40 may be implemented by a single processor or a plurality of processors, or may be incorporated in a circuit. The communication unit 41 of the controller 40 is configured to be communicable with a current sensor 50, voltage sensors 60, and a higher-level controller 75.

The battery system 100 includes a current sensor 50. The current sensor 50 measures a charging/discharging current flowing in the battery 10. In this embodiment, the current sensor 50 is provided between the battery 10 and the first main relay 20. The location of the current sensor 50 is not particularly limited. The charging/discharging current measured by the current sensor 50 is transmitted to the controller 40.

The battery system 100 includes voltage sensors 60. The voltage sensors 60 measure the voltage of the battery 10. In this embodiment, the voltage sensors 60 are provided for each of the battery modules 10A connected in series. The voltage sensors 60 may be able to measure the respective voltages of the corresponding battery modules 10A, or may be able to measure each of the voltages of the single cell batteries 10a that constitute each of the battery modules 10A. The voltages of the battery modules 10A measured by the respective voltage sensors 60 are transmitted to the controller 40.

The controller 40 is configured to be communicable with the higher-level controller 75. In this embodiment, the higher-level controller 75 is a controller of an electrically powered vehicle in which the battery system 100 and the load 70 are incorporated, which is also referred to as an on-board ECU.

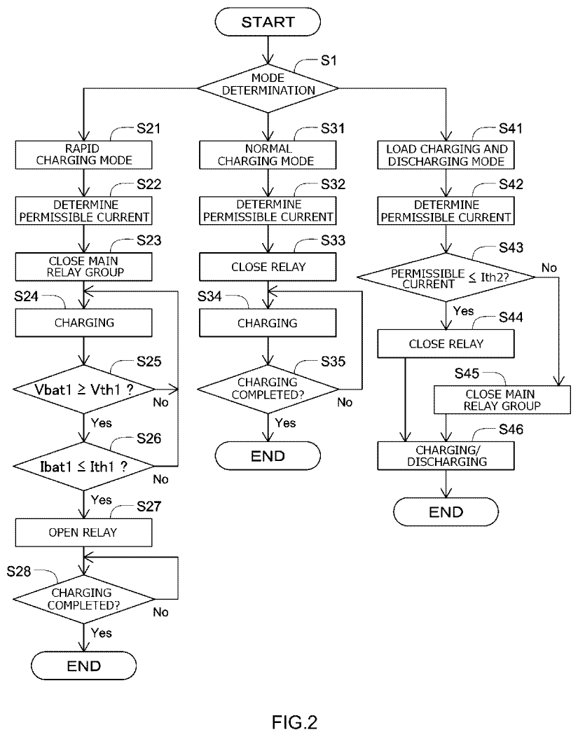

Hereinafter, controlling of switching the plurality of relays 21, 22, 31, and 32 between an open state and a closed state by the controller 40 will be described. FIG. 2 is a flowchart illustrating the processes executed by the controller 40. Upon starting up the battery system 100, controlling for the charging and discharging and the relays 21, 22, 31, and 32 is started. When starting up the battery system 100, the relays 21, 22, 31, 32 and the pre-charge relay 27 are in the open state.

At step S1 shown in FIG. 2, the mode determining unit 42 of the controller 40 determines the charging and discharging mode. Herein, the charging and discharging modes include a rapid charging mode, a normal charging mode, and a load charging and discharging mode. The rapid charging mode is a mode in which the rapid charger 83 is connected to the connecting portion 103. The normal charging mode is a mode in which the normal charger 82 is connected to the connecting portion 102. The load charging and discharging mode is a mode in which no charger 80 is connected to connecting portion 102 or 103 and electric power is supplied from the battery 10 through the connecting portion 101 to the load 70. In this embodiment, the load charging and discharging mode is set when the vehicle is not connected to the charger 80 but is travelling or at a standstill. It is also possible that, in the load charging and discharging mode, electric power may be supplied from the load 70 to the battery system 100.

The higher-level controller 75 identifies the connection status of the connecting portions 101 to 103, and transmits a signal according to the mode to be set to the controller 40. The controller 40 receives the signal transmitted from the higher-level controller 75. At step S1, the mode determining unit 42 determines the charging and discharging mode in response to the signal transmitted from the higher-level controller 75. When the mode determining unit 42 determines that the mode is the rapid charging mode, the process proceeds to step S21.

### Rapid Charging Mode

At step S21 shown in FIG. 2, the mode setting unit 43 sets the controlling of the controller 40 to the rapid charging mode. Next, at step S22 shown in FIG. 2, the permissible current determining unit 44 determines the permissible current of the battery 10 during charging. The permissible current may be determined based on various condition, such as the remaining capacity of the battery (i.e., SOC), the deterioration state of the battery (i.e., SOH), and the temperature of the battery. The permissible current may be determined taking into consideration the thermal limit characteristics of the components of the charging and discharging circuit. The permissible current may be determined according to the resistance of the component, the electric current flowing in the component, and the time at which electric current is scheduled to flow.

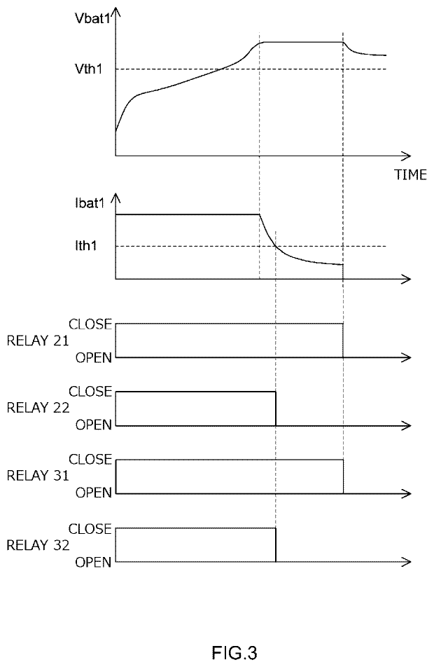

FIG. 3 is a graph illustrating the changes in current and voltage and the statuses of the relays 21, 22, 31, and 32 during charging. In this embodiment, the battery 10 is charged by what is called constant current-constant voltage (CCCV) charging. As illustrated in FIG. 3, the battery 10 is charged with a constant current until the voltage of the battery 10 reaches a predetermined threshold value Vth1. When the voltage of the battery 10 reaches higher than or equal to the predetermined threshold value Vth1, the battery 10 is then charged with a constant voltage. It should be noted that the charging of the battery 10 is not limited to CCCV charging, but other known charging techniques may be used.

At step S23 shown in FIG. 2, the instruction unit 45 controls the main relay groups (the relays 21 and 22 of the first main relay 20 and the relays 31 and 32 of the second main relay 30) to turn to the closed state. Thus, during rapid charging, the plurality of relays (the relays 21 and 22 of the first main relay 20 and the relays 31 and 32 of the second main relay 30) are switched to the closed state. Note that the relays 21 and 22 may be brought into the closed state after the pre-charge sequence.

At step S24 shown in FIG. 2, charging of the battery 10 is started. During charging, current Ibat1 of the battery 10 measured by the current sensor 50 and voltage Vbat1 of the battery 10 measured by the voltage sensors 60 are transmitted to the controller 40 when appropriate. The battery 10 is charged according the permissible current determined in step S22.

At step S25 shown in FIG. 2, the voltage determining unit 46 determines whether or not the voltage Vbat1 of the battery 10 is higher than or equal to the threshold value Vth1. If the voltage Vbat1 of the battery 10 is less than the threshold value Vth1 (NO), the process returns to step S24, and charging continues. At this time, the battery 10 continues to be charged at a constant current, and the voltage Vbat1 increases (see FIG. 3). If the voltage Vbat1 of the battery 10 reaches higher than or equal to the threshold value Vth1 (YES), the process proceeds to step S26. Sometime after the voltage Vbat1 has reached higher than or equal to the threshold value Vth1, the charging of the battery 10 is switched from constant current charging to constant voltage charging.

At step S26 shown in FIG. 2, the current determining unit 47 determines whether or not the current Ibat1 of the battery 10 is less than or equal to the threshold value Ith1. If the current Vbat1 of the battery 10 is greater than the threshold value Ith1 (NO), the process returns to step S24, and charging continues. As the battery 10 is charged with a constant voltage, the current Ibat1 decreases (see FIG. 3). If the current Ibat1 of the battery 10 reaches less than or equal to the threshold value Ith1 (YES), the process proceeds to step S27.

At step S27 shown in FIG. 2, the instruction unit 45 controls some of the relays among relays 21 and 22 in the first main relay 20 and the relays 31 and 32 in the second main relay 30 to turn to the open state. In this embodiment, the instruction unit 45 controls the relay 22 of the first main relay 20 and the relay 32 of the second main relay 30 to turn to the closed state. As described above, if the voltage Vbat1 is higher than or equal to a predetermined value and the current Ibat1 is less than or equal to a predetermined value during the rapid charging and discharging, the controller 40 switches at least one of the relays 22 and 32 among the plurality of relays 21, 22, 31, and 32 to the open state. This may reduce the power consumption required for driving the relays 22 and 32 while preventing the failure of the relays resulting from heat, when the current Ibat1 is low.

At step S28 shown in FIG. 2, the end determining unit 48 determines whether or not the charging of the battery 10 has ended. The condition for determining the end of charging is not limited to any particular condition. The condition for determining the end of charging may be set to be whether or not a target electric power has been charged. The condition for determining the end of charging may be set according to, for example, the remaining battery charge, voltage, current, charging time, and the like. If it is determined that the charging has not yet ended (NO), the charging continues. If it is determined that the charging has ended (YES), the charging of the battery 10 ends, and the supply of electric power from the rapid charger 83 is stopped. The instruction unit 45 may control the relays 21, 22, 31, and 32 to the open state.

In the above-described embodiment, the controller 40 switches the plurality of relays 21, 22, 31, and 32 to the closed state during rapid charging and discharging. As a result, the relays 21, 22, 31, and 32 are unlikely to cause a failure resulting from the deterioration due to heat, which may occur during rapid charging and discharging.

### Normal Charging Mode

At step S1 shown in FIG. 1, when the mode determining unit 42 determines that the mode is the normal charging mode, the process proceeds to step S31. At step S31 shown in FIG. 2, the mode setting unit 43 sets the controlling of the controller 40 to the normal charging mode. Subsequently, at step S32 shown in FIG. 2, the permissible current determining unit 44 determines a permissible current during charging of the battery 10.

At step S33 shown in FIG. 2, the instruction unit 45 controls the first main relay 20 and the second main relay 30 to be the closed state. In the normal charging mode, the relay 21 of the relays 21 and 22 in the first main relay 20 and the relay 31 of the relays 31 and 32 in the second main relay 30 are brought into the closed state. Note that the relay 21 may be brought into the closed state after the pre-charge sequence. The relays 22 and 32 remain in the open state.

At step S34 shown in FIG. 2, charging of the battery 10 is started. During charging, the current of the battery 10 measured by the current sensor 50 and the voltage of the battery 10 measured by the voltage sensors 60 are transmitted to the controller 40. The battery 10 may be charged by the above-mentioned CCCV charging. At step S34, the battery 10 is charged according the permissible current determined in step S32. At step S35 shown in FIG. 2, the end determining unit 48 determines whether or not the charging of the battery 10 has ended. In charging, it is possible to decide the method of charging as appropriate by comparing the voltage and/or current of the battery 10 with a predetermined threshold value.

At step S35 shown in FIG. 2, the end determining unit 48 determines whether or not the charging of the battery 10 has ended. The condition for determining the end of charging and the controlling of the relays may be the same as those in step S28, so the detailed description thereof will not be given further. If it is determined that the charging has not yet ended (NO), the charging continues. If it is determined that the charging has ended (YES), the charging of the battery 10 ends, and the supply of electric power from the normal charger 82 is stopped. The instruction unit 45 may control the relays 21 and 31 to the open state.

Herein, although the description has explained the cases in which the battery 10 of the battery system 100 undergoes the rapid charging or the normal charging, the embodiments are not limited thereto. The processing of the controller 40 described above is also applicable to the cases in which electric power is supplied (discharged) from the battery 10 of the battery system 100 to the load 70 or the like. For example, when the usage modes of the battery system 100 include rapid discharging and normal discharging, “rapid charging” and “normal charging” described above can be read as “rapid discharging” and “normal discharging” as appropriate.

### Load Charging and Discharging Mode

At step S1 shown in FIG. 1, when the mode determining unit 42 determines that the mode is the load charging and discharging mode, the process proceeds to step S41. At step S41 shown in FIG. 2, the mode setting unit 43 sets the controlling of the controller 40 to the load charging and discharging mode. Next, at step S42 shown in FIG. 2, the permissible current determining unit 44 determines the permissible current of the battery 10 during charging and discharging.

At step S43 shown in FIG. 2, the current determining unit 47 determines whether or not the permissible current is less than or equal to a threshold value Ith2. If the permissible current is less than or equal to the threshold value Ith2 (YES), the process proceeds to step S44. At step S44, the relay 21 of the relays 21 and 22 in the first main relay 20 and the relay 31 of the relays 31 and 32 in the second main relay 30 are brought into the closed state, and the process proceeds to step S46. The relay 21 may be brought into the closed state after the pre-charge sequence. Note that the relays 22 and 32 remain in the open state. Thus, the controller 40 switches a plurality of relays 22 and 32 contained in the relay groups 21, 22, 31, and 32 between the closed state and the open state according to the permissible current. This may reduce the power consumption required for driving the relays 22 and 32 while preventing the failures of the relays 21 and 31 resulting from heat.

At step S43, if the permissible current is greater than the threshold value Ith2 (NO), the process proceeds to step S45. At step S45, the main relay groups (i.e., the relays 21 and 22 in the first main relay 20 and the relays 31 and 32 in the second main relay 30) are brought into the closed state, and the process proceeds to step S46. The relays 21 and 22 may be brought into the closed state after the pre-charge sequence.

At step S46 shown in FIG. 2, charging and discharging of the battery 10 are started. During charging and discharging, the above-described determination of whether or not the permissible current is less than or equal to the threshold value Ith2 may be carried out by the current determining unit 47. For example, the determination of permissible current and the determination of whether or not the permissible current is less than or equal to the threshold value Ith2 may be carried out at predetermined time intervals. It is also possible that the relays 21, 22, 31, and 32 may be switched between the closed state and the open state as appropriate according to the relationship between the permissible current and the threshold value Ith2. For example, the above-described processing of steps S42 to S46 may be repeated.

In the load charging and discharging mode, the permissible current may fluctuate considerably depending on, for example, the travel conditions of the vehicle. Accordingly, the magnitude relationship between threshold value Ith2 and permissible current may change over time. At times, the permissible current may become less than or equal to the threshold value Ith2, or greater than the threshold value Ith2. When the permissible current reaches a current less than or equal to the threshold value Ith2 from a current greater than the threshold value Ith2, the instruction unit 45 may switch the relays 22 and 32 of the plurality of relays 21, 22, 31, and 32 to the open state. The memory storage unit 49 memorizes that the relays 22 and 32 have been switched to the open state. Thereafter, when the permissible current reaches a current greater than the threshold value Ith2 from a current less than or equal to the threshold value Ith2, the instruction unit 45 may switches the relays 22 and 32, which have been in the open state, to the closed state. Thereafter, when the permissible current again reaches a current less than or equal to the threshold value Ith2 from a current greater than the threshold value Ith2, the instruction unit 45 may switch at least one of the plurality of relays 21, 22, 31, and 32 to the open state. The memory storage unit 49 memorizes that the relays 22 and 32 have been last switched from the closed state to the open state. The instruction unit 45 switches the relays 21 and 31, the relays other than the relays 22 and 32 that have been last switched from the closed state to the open state.

As described above, when the controller 40 switches at least one of the plurality of relays 21, 22, 31, and 32 from the closed state to the open state, the controller 40 may preferentially switch, from the closed state to the open state, one of the relays that have not been last switched from the closed state to the open state. Switching one of the relays that have not been last switched from the closed state to the open state from the closed state to the open state may reduce unevenness in the time during which the plurality of relays 21, 22, 31, and 32 are in the closed state. As a result, the relays 21, 22, 31, and 32 are unlikely to cause a failure such as contact welding (a short-circuit failure between energized lines in the case of semiconductor relays) due to heat generation that is associated with the charging/discharging current.

When the use of the vehicle ends, the battery system 100 is shut down. At the time of shutting down the battery system 100, the instruction unit 45 may control the relays 21, 22, 31, and 32 to the open state.

Furthermore, the battery system may also be provided with a mechanism that ensures safety even when the relays undergo the contact welding.

### Battery System 100A

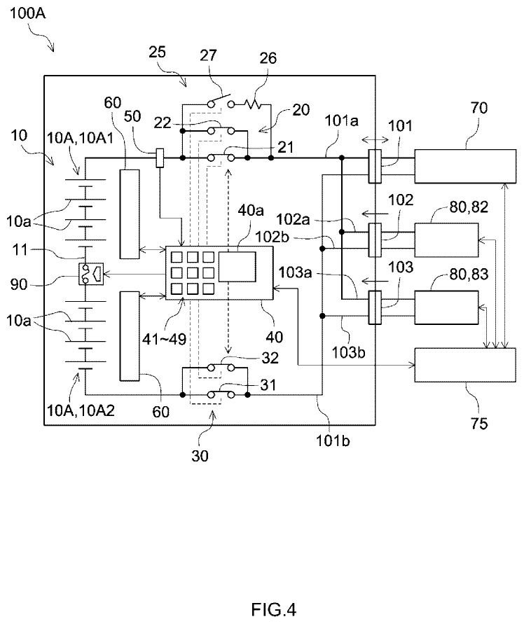

FIG. 4 is a schematic view illustrating a battery system 100A. In FIG. 4, identical reference characters are used to designate the elements or features illustrated in FIG. 1, and repetitive description thereof may be omitted as appropriate. As illustrated in FIG. 4, the battery unit 100A includes a battery 10, a first main relay 20, and a second main relay 30, and a pyro-fuse 90. The pyro-fuse 90 is provided on a conductive path passing in the battery 10. The pyro-fuse 90 is a gunpowder-based current interrupting device. The pyro-fuse 90 contains gunpowder to interrupt the conductive path by detonating the gunpowder. The pyro-fuse 90 is configured to receive a signal from the controller 40. In this embodiment, the pyro-fuse 90 is disposed on a connecting wire 11 connecting two battery modules 10A1 and 10A2.

The controller 40 includes a welding diagnostic device 40a. The welding diagnostic device 40a diagnoses at least one of the first main relay 20 and the second main relay 30 as whether or not to have been welded. The welding diagnostic device 40a may carry out the diagnosis by detecting the electric current flowing in each of the relays 21, 22, 31, and 32 or by detecting the voltage applied to each of the relays 21, 22, 31, and 32. For example, if the detected current or voltage is higher than or equal to a threshold value when the relays 21, 22, 31, and 32 are controlled to the open state, the one of the relays 21, 22, 31, and 32 that shows the current or voltage higher than or equal to the threshold value may be diagnosed as having been welded. When the welding diagnostic device 40a detects that at least one of the first main relay 20 and the second main relay 30 has been welded, the welding diagnostic device 40a transmits a shut-down signal to the pyro-fuse 90. The pyro-fuse 90 that receives the shut-down signal causes the conductive path (the connecting wire 11 in this embodiment) to rupture.

The first main relay 20 and the second main relay 30 may cause welding because of rapid charging and discharging, long-term use, and the like. When one of the parallel connected relays 21 and 22 or the parallel connected relays 31 and 32 causes welding, the other one of the relays that does not cause welding may show a lower resistance, resulting in a bias in the charging/discharging current. It is feared that when the charging/discharging current is biased toward one of the relays, the one of the relays passing a higher current may cause unintended heat generation.

In the above-described embodiment, when the welding diagnostic device 40a detects that at least one of the first main relay 20 and the second main relay 30 has been welded, the pyro-fuse 90 ruptures the conductive path. Rupturing the conductive path with the pyro-fuse 90 at the time of welding of a relay may prevent the first main relay 20 and the second main relay 30 from causing unintended heat generation. It should be noted that even when each of the first main relay 20 and the second main relay 30 contains one relay, it is possible to prevent unintended heat generation.

In the above-described embodiment, the pyro-fuse 90 is disposed between the battery modules 10A1 and 10A2. As a result, the connection between the battery modules 10A1 and 10A2 can be physically cut off when welding of a relay occurs. This may improve safety in the inspection work for the battery system 100A after the rupture of the shut-down path. Note that the pyro-fuse 90 is not necessarily be disposed between the battery modules 10A1 and 10A2, but the pyro-fuse 90 may be disposed on a conductive path for the battery 10, the load 70, and the charger 80.

Various embodiments of the technology according to the present disclosure have been described hereinabove. Unless specifically stated otherwise, the embodiments described herein do not limit the scope of the present disclosure. It should be noted that various other modifications and alterations may be possible in the embodiments of the technology disclosed herein. In addition, the features, structures, or steps described herein may be omitted as appropriate, or may be combined in any suitable combinations, unless specifically stated otherwise. In addition, the present description includes the disclosure as set forth in the following items.

### Item 1

A battery system including:
a battery including a positive electrode and a negative electrode;
a first main relay connected in series to the positive electrode of the battery; and
a second main relay connected in series to the negative electrode of the battery; wherein:
at least one of the first main relay and the second main relay includes a relay group including a plurality of relays connected in parallel; and
the plurality of relays are each individually controlled to switch between a closed state and an open state.

### Item 2

The battery system according to item 1, further including:
a controller controlling the plurality of relays to switch between the closed state and the open state; and wherein
the controller switches the plurality of relays to the closed state during rapid charging and discharging.

### Item 3

The battery system according to item 2, further including:
a voltage sensor measuring a voltage of the battery; and
a current sensor measuring a charging/discharging current flowing in the battery; and wherein
the controller switches at least one of the plurality of relays to the open state if the voltage is higher than or equal to a predetermined value and the charging/discharging current is less than or equal to a predetermined value during rapid charging and discharging.

### Item 4

The battery system according to any one of items 1 to 3, further including:
a controller controlling the plurality of relays to switch between the closed state and the open state; and
a current sensor measuring a charging/discharging current flowing in the battery; and wherein
the controller switches the plurality of relays contained in the relay group between the closed state and the open state according to a permissible current.

### Item 5

The battery system according to any one of items 1 to 4, further including:
a controller controlling the plurality of relays to switch between the closed state and the open state; and wherein
when switching at least one of the plurality of relays from the closed state to the open state, the controller preferentially switches, from the closed state to the open state, one of the relays that has not been last switched from the closed state to the open state.

### Item 6

The battery system according to any one of items 1 to 5, wherein both the first main relay and the second main relay include a relay group including a plurality of relays connected in parallel.

### Item 7

The battery system according to any one of items 1 to 6, further including:
a pyro-fuse disposed on a conductive path of a charging/discharging current flowing in the battery; wherein:
the controller includes a welding diagnostic device detecting that at least one of the first main relay and the second main relay has been welded; and
the pyro-fuse ruptures the conductive path when the welding diagnostic device detects that at least one of the first main relay and the second main relay has been welded.

What is claimed is:

1. A battery system comprising:
a battery including a positive electrode and a negative electrode;
a first main relay connected in series to the positive electrode of the battery; and
a second main relay connected in series to the negative electrode of the battery; wherein:
at least one of the first main relay and the second main relay includes a relay group including a plurality of relays connected in parallel; and
the plurality of relays are each individually controlled to switch between a closed state and an open state.

2. The battery system according to claim 1, further comprising:
a controller controlling the plurality of relays to switch between the closed state and the open state; and wherein
the controller switches the plurality of relays to the closed state during rapid charging and discharging.

3. The battery system according to claim 2, further comprising:
a voltage sensor measuring a voltage of the battery; and
a current sensor measuring a charging/discharging current flowing in the battery; and wherein
the controller switches at least one of the plurality of relays to the open state if the voltage is higher than or equal to a predetermined value and the charging/discharging current is less than or equal to a predetermined value during rapid charging and discharging.

4. The battery system according to claim 1, further comprising:
a controller controlling the plurality of relays to switch between the closed state and the open state; and
a current sensor measuring a charging/discharging current flowing in the battery; and wherein
the controller switches the plurality of relays contained in the relay group between the closed state and the open state according to a permissible current.

5. The battery system according to claim 1, further comprising:
a controller controlling the plurality of relays to switch between the closed state and the open state; and wherein
when switching at least one of the plurality of relays from the closed state to the open state, the controller preferentially switches, from the closed state to the open state, one of the relays that has not been last switched from the closed state to the open state.

6. The battery system according to claim 1, wherein both the first main relay and the second main relay include a relay group including a plurality of relays connected in parallel.

7. The battery system according to claim 1, further comprising:
a pyro-fuse disposed on a conductive path of a charging/discharging current flowing in the battery; wherein:
the controller includes a welding diagnostic device detecting that at least one of the first main relay and the second main relay has been welded; and
the pyro-fuse ruptures the conductive path when the welding diagnostic device detects that at least one of the first main relay and the second main relay has been welded.
